(19) United States
(12) Patent Application Publication
(10) Pub. No.: US 2006/0043072 A1
(43) Pub. Date: Mar. 2, 2006

(54) Method for planarizing polysilicon

(75) Inventors: Yu-Cheng Chen, Taipei (TW); Jia-Xing Lin, Taipei (TW); Chi-Lin Chen, Hsinchu (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Industrial Technology Research Institute

(21) Appl. No.: 11/194,314

(22) Filed: Aug. 1, 2005

Related U.S. Application Data
(63) Continuation-in-part of application No. 10/358,184, filed on Feb. 5, 2003, now abandoned.

(51) Int. Cl. C03C 15/00

(52) U.S. Cl. 216/88; 216/99; 438/753

(57) ABSTRACT

A method for planarizing polysilicon comprises providing a substrate, forming a dielectric layer on the substrate, forming an amorphous silicon film on the dielectric layer, etching the amorphous silicon film to remove native oxide formed on a surface of the amorphous silicon film, exposing the surface of the amorphous silicon film to a first radiation source to polycrystallize the amorphous silicon film into a polysilicon film, etching the polysilicon film to remove weak bonded silicon formed on a surface of the polysilicon film, and exposing the surface of the polysilicon film to a second radiation source to reflow the polysilicon film.

### CROSS-REFERENCE TO RELATED APPLICATIONS

This application is a continuation-in-part of U.S. patent application Ser. No. 10/358,184, filed Feb. 5, 2003, which is herein incorporated by reference in its entirety.

### BACKGROUND OF THE INVENTION

1. Technical Field of the Invention

The present invention generally relates to a method for planarizing polysilicon and, more particularly, to a method which includes providing a substrate with polysilicon on the surface, etching the surface of the polysilicon to initially reduce surface roughness, and laser annealing the polysilicon to partially melt the polysilicon to planarize the surface thereof.

2. Description of the Related Art

Polysilicon thin film transistors (“TFTs”) have been widely used in various fields, such as active matrix liquid crystal displays (“LCDs”), active matrix organic light-emitting displays, static random access memory (“SRAM”) devices, projectors and contact type image sensors. A problem with current polysilicon TFT processes is surface roughness, which becomes more serious as grain size of polysilicon continues to increase. The surface roughness issue is disadvantageous for the electrical properties of the devices in, for example, breakdown electrical field, leakage current, sub-threshold swing, threshold voltage and mobility of electron/hole.

Undesirable surface roughness of polysilicon may directly impact product quality and yield. Hence, in a semiconductor process where a gate insulator 12 is formed on a polysilicon layer 10, as shown in FIG. 1, uneven thickness of polysilicon layer 10 results in irregular thickness of gate insulator layer 12. Thus, ridges in polysilicon layer 10 induce greater local electrical field. This shortcoming increases the leakage current, thereby causing easier breakdown of gate insulator 12. Reliability of devices is adversely affected, and may even become worse in the case of thin gate insulator devices. Furthermore, during photolithography processes, undesirable surface roughness of polysilicon may cause disorder scattering, resulting in inaccuracy of pattern size definition.

In connection with the surface roughness of polysilicon, there are a number of research papers proposing the improvement of electrical characteristics by reducing the surface roughness of polysilicon. An example of the research papers is “Fabrication of Thin Film Transistors by Chemical Mechanical Polished Polycrystalline Silicon Films” by C. Y. Chang, published in Electron Device letters, vol. 17, No. 3, March 1996 of IEEE (International Electrical and Electronic Engineering). Chang stated that surface roughness (RMS) of polysilicon is decreased from 90 angstroms to 37 angstroms by chemical mechanical polishing (“CMP”). This provides improvement in electron/hole mobility, threshold voltage, and sub-threshold swing. Another example of the research papers is “Improved Thin-Film Transistor (TFT) Characteristics on Chemical-Mechanically Polished Polycrystalline Silicon Film” by Alain C. K. Chan, published in IEEE Electron Devices Meeting 1999 Proceedings, June 1999. Chan indicated that surface roughness of polysilicon improved by CMP has positive effect on performance of TFT devices.

The trend of flat panel display fabrication is to fabricate devices of a smaller size on substrates of a larger area, which facilitates mass-production of the devices, for example, LTPS-TFTs. Dimension of the substrates can reach 1 m×1 m or greater. Therefore, applicability of a planarization method for large-size polysilicon substrates must be considered. Current planarization using CMP, however, is not suitable because no CMP equipment is designed for use with such large-size polysilicon substrates. CMP may be no longer applicable in the future for mass production of large-size polysilicon substrates. Furthermore, the surface roughness of polysilicon after CMP processing may still be as high as 30 or 40 angstroms, which is not acceptable for advanced TFT devices of reduced dimensions. Thus, it is desirable to have a method for planarizing polysilicon on large-size polysilicon substrates while reducing the surface roughness of the polysilicon.

### BRIEF SUMMARY OF THE INVENTION

To overcome the above problems, an object of the invention is to provide a method for planarizing polysilicon that can be used with large-size polysilicon substrates. The method includes etching the polysilicon to change its surface morphology by the removal of native oxide, weak bonded silicon, and impurities in the polysilicon to initially lower the surface roughness. The etching process is followed by a laser annealing process to partially melt the polysilicon so that the surface of polysilicon is reconstructed to form a smooth surface. By adjusting etching and laser annealing, a relatively smooth polysilicon surface can be obtained.

In order to achieve the above objects, there is provided a method for planarizing polysilicon, including providing a substrate formed with polysilicon on the surface, changing surface morphology of the polysilicon by etching to initially reduce surface roughness, and laser annealing the polysilicon to partially melt and thereby planarize the surface thereof.

In the method of the present invention, the substrate includes one of a glass, quartz, silicon wafer, plastic or silicon on insulator (“SOI”) substrate. The method provided in the present invention is applicable to substrates on which polysilicon is formed.

In the method described above, etching is carried out by either wet or dry etching. Preferable solution for wet etching is buffered oxide etchant (“BOE”) or diluted hydrogen fluoride (“DHF”). Dry etching is not limited to a particular method, as long as undesired materials such as native oxide, weak bonded silicon and impurities on the polysilicon are removed. As for laser annealing, parameters may vary as laser equipments vary. Laser annealing is performed so that polysilicon is partially melted for lattice reconstruction, thus forming a smooth surface.

According to the method of the present invention, after the polysilicon surface is modified by etching, laser annealing is then carried out to obtain a smooth surface. The method of the present invention advantageously achieves reduced surface roughness and is suitable for use in large-size polysilicon substrates.

In accordance with an embodiment of the present invention, there is provided a method for planarizing polysilicon that comprises providing a substrate, forming a dielectric layer on the substrate, forming an amorphous silicon film on the dielectric layer, etching the amorphous silicon film to remove native oxide formed on a surface of the amorphous silicon film, exposing the surface of the amorphous silicon film to a first radiation source to polycrystallize the amorphous silicon film into a polysilicon film, etching the polysilicon film to remove weak bonded silicon formed on a surface of the polysilicon film, and exposing the surface of the polysilicon film to a second radiation source to reflow the polysilicon film.

Also in accordance with the present invention, there is provided a method for planarizing polysilicon that comprises forming an amorphous silicon film over a substrate, etching the amorphous silicon film in a first etchant comprising a first density of a hydrofluoric acid, exposing the amorphous silicon film to a first radiation source to polycrystallize the amorphous silicon film into a polysilicon film, etching the polysilicon film in a second etchant comprising a second density of a hydrofluoric acid greater than the first density, and exposing the polysilicon film to a second radiation source to reflow the polysilicon film.

Further in accordance with the present invention, there is provided a method for planarizing polysilicon that comprises forming an amorphous silicon film over a substrate, removing native oxide formed on a surface of the amorphous silicon film by a first etchant having a first density, exposing the surface of the amorphous silicon film to a first radiation source to polycrystallize the amorphous silicon film into a polysilicon film, the polysilicon film having a plurality of ridges formed on a surface thereof, recessing the ridges by using a second etchant having a second density greater than the first density, and exposing the surface of the polysilicon film to a second radiation source to reflow the polysilicon film.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a TEM (Transmission Electron Microscopy) photograph of a polysilicon layer and a gate insulator layer before planarization;

FIG. 2 illustrates a process flow of a method for planarizing polysilicon in accordance with one embodiment of the present invention;

FIG. 3 illustrates the reduced surface roughness for the method according to the embodiment of the present invention;

FIG. 4A is a TEM photograph of a polysilicon before planarization;

FIG. 4B is a TEM photograph showing the polysilicon having reduced surface roughness according to one embodiment of the present invention;

FIG. 5A is an AFM (Atomic Force Microscope) stereograph of a polysilicon before planarization;

FIG. 5B is an AFM stereograph of the polysilicon according to the embodiment of the present invention;

FIGS. 6A to 6F are schematic diagrams showing a method for planarizing polysilicon in accordance with another embodiment of the present invention;

FIG. 7A is an SEM (Scanning Electron Microscope) photograph showing a polysilicon surface before an etching process;

FIG. 7B is an SEM photograph showing a polysilicon surface after an etching process in accordance with one embodiment of the present invention;

FIG. 8A is a drain current (Id) versus gate voltage (Vg) curve of a TFT having a polysilicon surface without planarization process; and

FIG. 8B is an Id-Vg curve of a TFT having a polysilicon surface planarized in accordance with a method of the present invention.

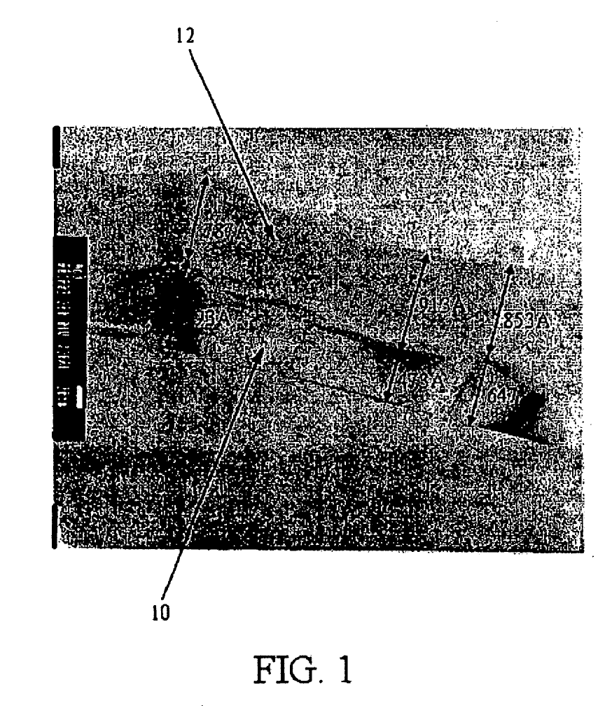

### DETAILED DESCRIPTION OF THE INVENTION

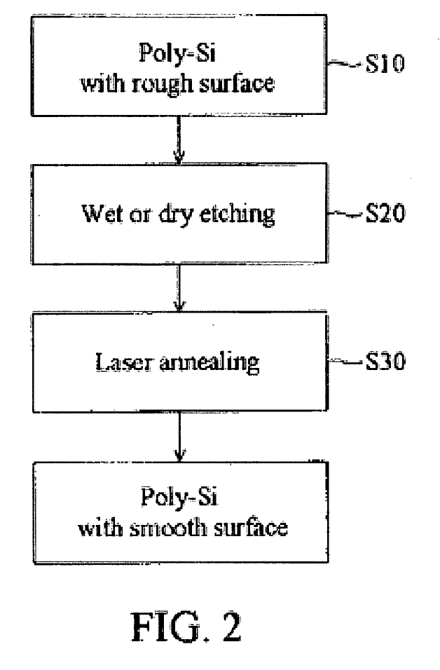

FIG. 2 illustrates a process flow of a method for planarizing polysilicon in accordance with one embodiment of the present invention. Referring to FIG. 2, a substrate formed with polysilicon on a surface is provided at step S10. Formation of the polysilicon is not restricted to a particular method, and may be attained by, for example, laser crystallization or chemical vapor deposition. Next, at step S20, an etching process is carried out to change the surface structure of the polysilicon. In one embodiment, buffered oxide etchant (“BOE”) is used as an etching solution. During the etching process, native oxide, weak bonded silicon and impurities in the polysilicon surface are removed. Components of the BOE solution are HF, NH₄F and H₂O. A preferable ratio of the BOE to water is 1:300˜1:0. In another embodiment, diluted hydrogen fluoride (“DHF”) is used as an etching solution. The preferable ratio of hydrogen fluoride to water is 1:600˜1:1. Preferable time for wet etching is less than 600 seconds. In other embodiments, a dry etching process such as plasma etching using CF₄ gas is conducted.

Next, the polysilicon is subjected to laser annealing at step S30. Excimer laser is adopted in this embodiment. Relevant parameters are: the repeated pulse overlap ratio is preferably 98%; 1 atm Nitrogen is the preferable surrounding; frequency is preferably 1 Hz to 400 Hz, and more preferably 200 Hz; wavelength is preferably 157 nm to 351 nm, and more preferably 308 nm; energy density is preferably lower than the threshold energy density for polysilicon to completely melt, i.e. 250˜350 mJ/cm²; time for laser pulse is preferably 10 ns to 1 ms, and more preferably 55 ns; and preferable temperature of the substrate is room temperature to 600° C.

The laser annealing step allows partial melting of the polysilicon surface, and consequently the lattice structure is reconstructed. The surface of the polysilicon is thus planarized to reduce surface roughness. Parameters, such as temperature, pressure, laser energy are varied according to the type of equipment used.

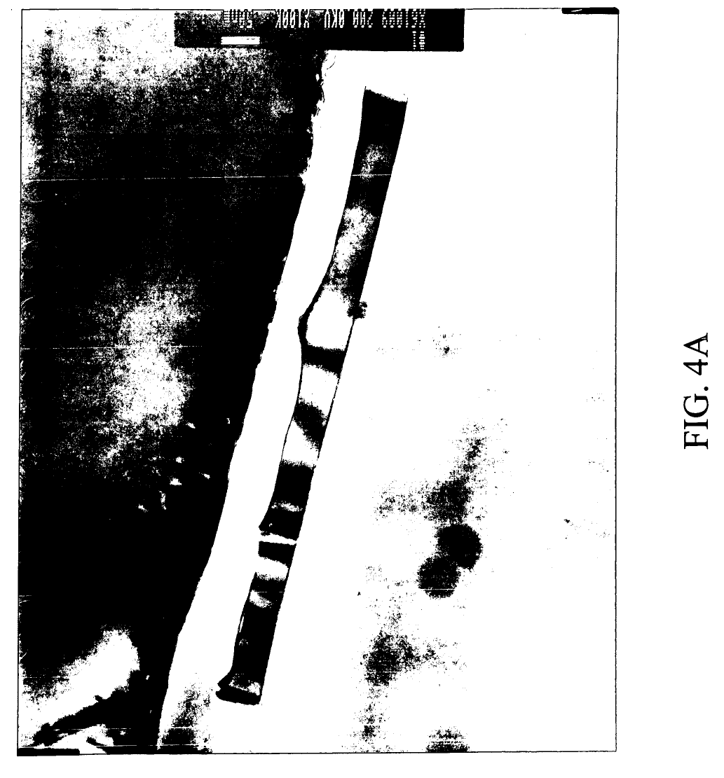

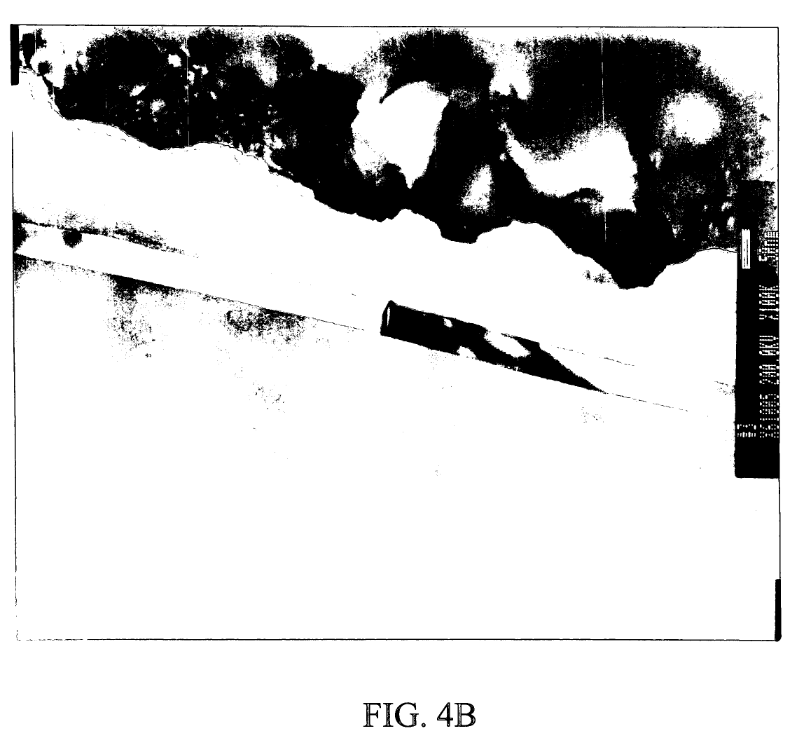

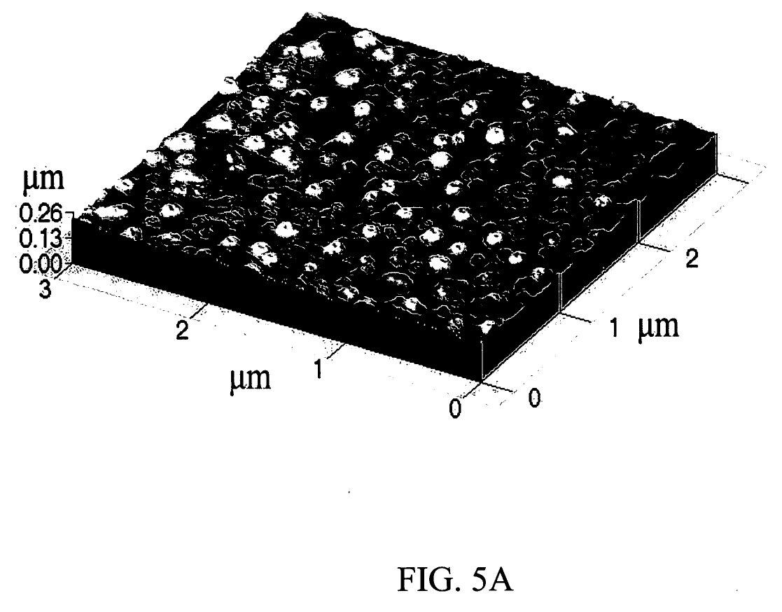

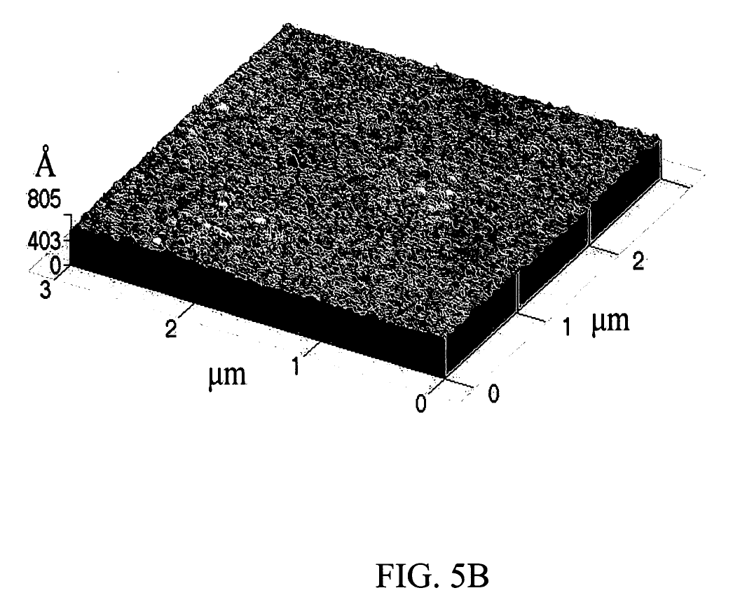

FIG. 4A is a TEM (Transmission Electron Microscopy) photograph of a polysilicon before planarization. FIG. 4B is a TEM photograph showing the polysilicon having reduced surface roughness according to the embodiment of the present invention. FIG. 5A is an AFM (Atomic Force Microscope) stereograph of a polysilicon before planarization. FIG. 5B is an AFM stereograph of the polysilicon according to the embodiment. It is observed from FIG. 4A that ridges in the original polysilicon are planarized in FIG. 4B. A very smooth polysilicon surface is obtained without ridges between the polysilicon and the gate insulator layer.

Similarly, surface roughness of polysilicon is greatly reduced from 120 angstroms to 18 angstroms, only 15% of the original surface roughness, as shown in FIGS. 5A and 5B. In comparison to the conventional method using CMP, where surface roughness is reduced by 50%, the method provided in the present invention provide excellent results of planarizing polysilicon.

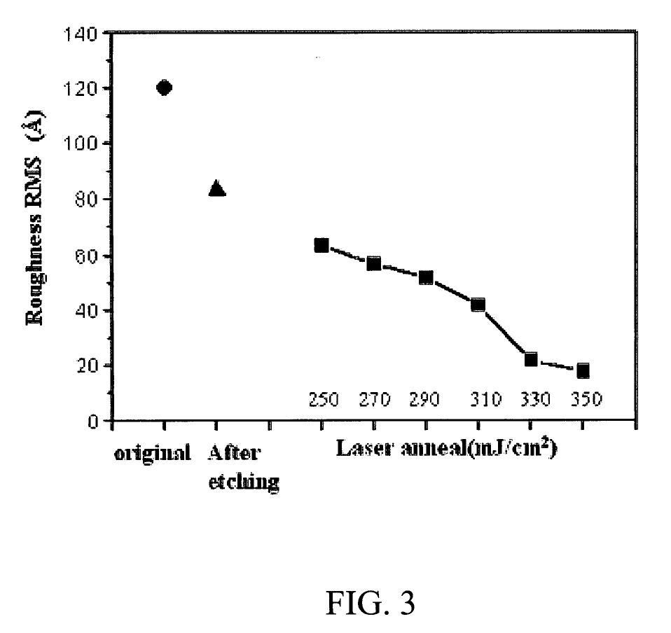

From the above results and FIG. 3, which illustrates the gradual results of planarizing polysilicon, original polysilicon (●), after etching (▴) and laser annealing (▪), surface roughness (RMS) of polysilicon is reduced by 30-95%. Generally, surface roughness (RMS) is reduced to less than 20 angstroms. Therefore, it is concluded that the method for planarizing polysilicon provided in the present invention is capable of obtaining polysilicon with a smoother surface. Furthermore, this method is not limited by the dimensions of the substrate, and can be easily adopted in the LTPS TFT process.

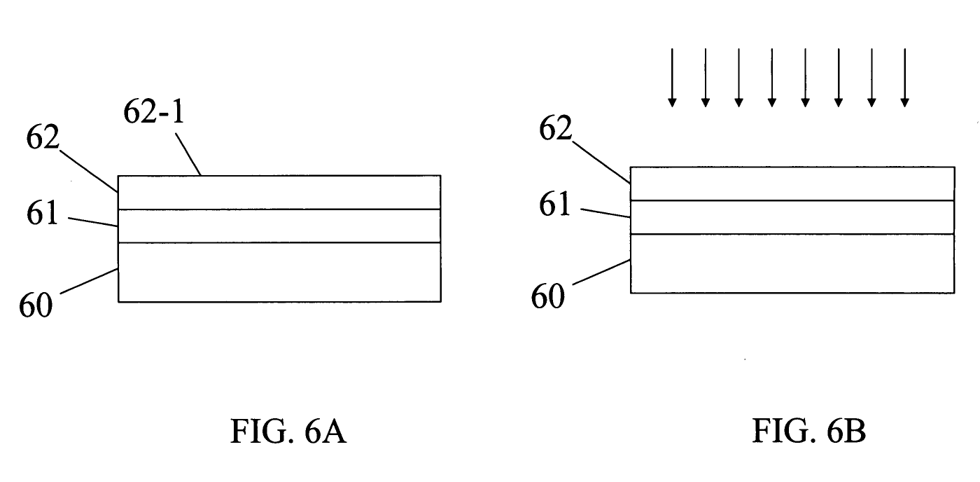

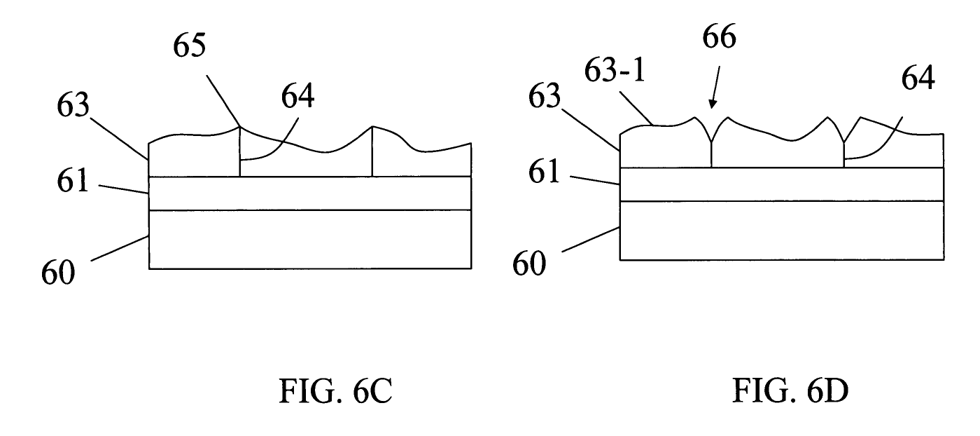

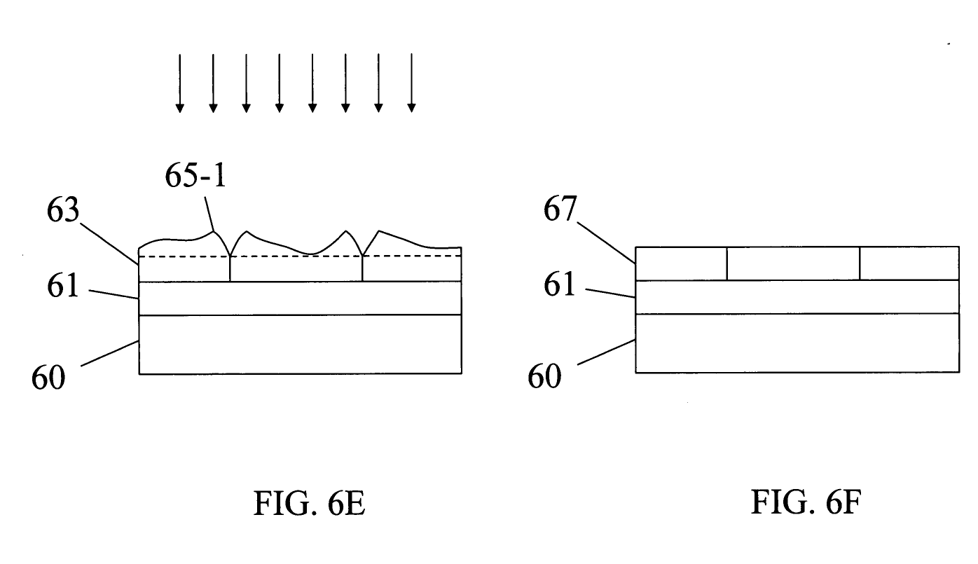

FIGS. 6A to 6F are schematic diagrams showing a method for planarizing polysilicon in accordance with another embodiment of the present invention. Referring to FIG. 6A, a glass substrate 60 having a size as large as 370×470 mm² is defined. A dielectric layer 61 is formed over substrate 60 by, for example, chemical vapor deposition (“CVD”). Dielectric layer 61 includes one of silicon dioxide (SiO₂) or silicon nitride (SiN_{X}), which functions to serve as a buffer layer. In another embodiment, dielectric layer 61 includes a double-layered film of SiO₂ and SiN_{X}. Next, an amorphous silicon film 62 is formed over dielectric layer 61 by, for example, plasma enhanced chemical vapor deposition (“PECVD”) to a thickness of approximately 500 angstroms (Å).

Subsequent to the formation of amorphous silicon film 62, a dehydrogenation process is performed by annealing amorphous silicon film 62 at approximately 450° C. in a vacuum ambience for approximately one and half an hours. The dehydrogenation process reduces the hydrogen density in amorphous silicon film 62 to a level below approximately 2 atom %.

Next, a first etching process is performed to remove native oxide formed on a surface 62-1 of amorphous silicon film 62 so as to reduce the density of oxygen atoms in amorphous silicon film 62 and prevent oxidation of surface 62-1 of amorphous film 62. In one embodiment, a wet etching is performed at room temperature (approximately 25° C.) by immersing amorphous silicon film 62 in a buffer hydrofluoric (BHF) solution. The BHF solution includes approximately a 40% solution of NH₄F and a 49% solution of HF. The ratio of the HF solution to the NH₄F solution is approximately 1:20 to 1:30 The time duration for the wet etching is approximately 20 to 30 seconds.

Subsequent to the first etching process, referring to FIG. 6B, a first laser radiation process is performed by radiating an excimer laser to amorphous silicon film 62 to polycrystallize amorphous silicon film 62. In one embodiment according to the present invention, an XeCl excimer laser beam having a frequency of approximately 200 Hz (Hertz) and a pulse width of 55 ns (nanosecond) is employed at room temperature in a nitrogen (N₂) ambience of approximately 1 atm. The energy density of the XeCl excimer laser beam is approximately 370 mJ/cm² with an overlap ratio of approximately 98%. This energy density is smaller than that required to completely melt amorphous silicon film 62, approximately 380 mJ/cm².

Referring to FIG. 6C, a polysilicon film 63 of approximately 500 Å is formed after the first laser radiation process. During crystallization, silicon transform from liquid phase to solid phase. However, density change of silicon during solidification appears to drive liquid silicon toward the last areas of solidification. This phenomenon causes thickness variation, i.e., ridges 65, at grain boundaries 64. A root-mean-square (RMS) value of the surface roughness of polysilicon film 63 measured by an atomic force microscope (“AFM”) is approximately 120 Å.

Next, referring to FIG. 6D, a second etching process is performed to remove weak bonded silicon on a surface 63-1 of polysilicon film 63 at grain boundaries 64. A plurality of slot-like recesses 66 are formed on surface 63-1 of polysilicon film 63 at grain boundaries 64, which initially reduce the surface roughness of polysilicon film 63 and substantially alleviate surface stress of polysilicon film 63. In one embodiment according to the present invention, a wet etching is performed at room temperature to polysilicon film 63 in a buffer hydrofluoric (BHF) solution. The BHF solution includes approximately a 40% solution of NH₄F and a 49% solution of HF. The ratio of the HF solution to the NH₄F solution is approximately 1:2 to 1:4, which is relatively higher than the ratio of BHF used in the first etching process in order to remove weak bonded silicon formed on surface 63-1 of polysilicon film 63 at grain boundaries 64. The time duration for the wet etching is approximately 60 to 300 seconds, and preferably 120 seconds. The levels of surface roughness of polysilicon film 63 after a wet etching of 60, 120 and 300 seconds are approximately 90, 82 and 75 Å, respectively. Furthermore, recesses 66 may become deeper as the etching time is longer. In other embodiments, a second etching solution selected from one of a KOH solution, a solution of CrO₃ and HF or a solution of HNO₃ and HF is used as an etchant in the second etching process.

Next, referring to FIG. 6E, a second laser radiation process is performed by radiating an excimer laser to polysilicon film 63. The second laser radiation process allows partial melting of polysilicon film 63 and causes the melted silicon to reflow from ridges 65-1. Afterward the liquid silicon solidifies from under-melted polysilicon. Because solidification occurs from bottom to top, there is less driving force to from ridges. Consequently, surface of polysilicon film 63 is flattened. In one embodiment according to the present invention, an XeCl excimer laser beam having a frequency of approximately 200 to 300 Hz and a pulse width of 55 ns is employed at room temperature in a nitrogen (N₂) ambience of approximately 1 atm. The energy density of the XeCl excimer laser beam is approximately 250 to 350 mJ/cm², preferably 350 mJ/cm², with an overlap ratio of approximately 90 to 95%. With recesses 66 formed on surface 63-1, this energy density is smaller than that of the first laser radiation process by at least 20 mJ/cm². A smaller laser energy facilitates retaining the grain size of polysilicon and prevents agglomeration holes during laser processing, which would otherwise occur in a high-density laser process. Furthermore, a smaller overlap ratio enhances the throughput of laser radiation process.

In the second etching process by reference to FIG. 6D, if a lower density of BHF solution is used, for example, a density of a level that only etches off an oxidation layer (not shown) formed on surface 63-1 of polysilicon film 63 without forming recesses 66 on surface 63-1, the surface roughness of polysilicon film 63 will not be reduced to a desirable level by a subsequent processing of the same second laser radiation. Consequently, in the second laser radiation process, a laser of a higher energy density, for example, a level equal to or higher than 370 mJ/cm², must be used to reflow polysilicon film 63. Such a laser processing may incur agglomeration holes when its overlap ratio is greater than 95%, disadvantageously resulting in a discontinuous polysilicon film.

After the second laser radiation process, referring to FIG. 6F, a polysilicon film 67 having a flattened surface is achieved. The surface roughness of polysilicon film 67 is approximately 18 Å.

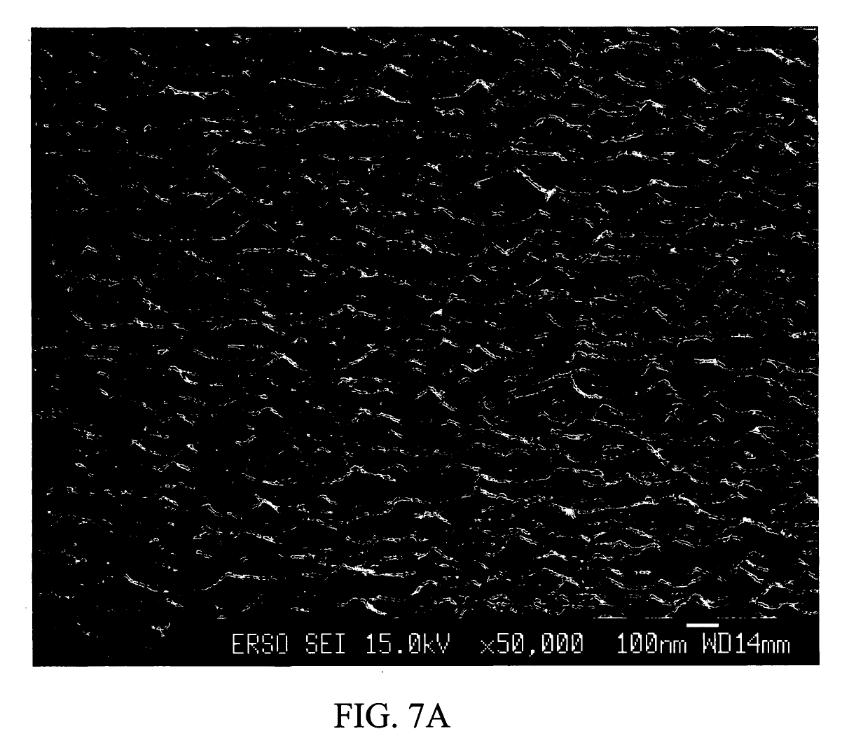

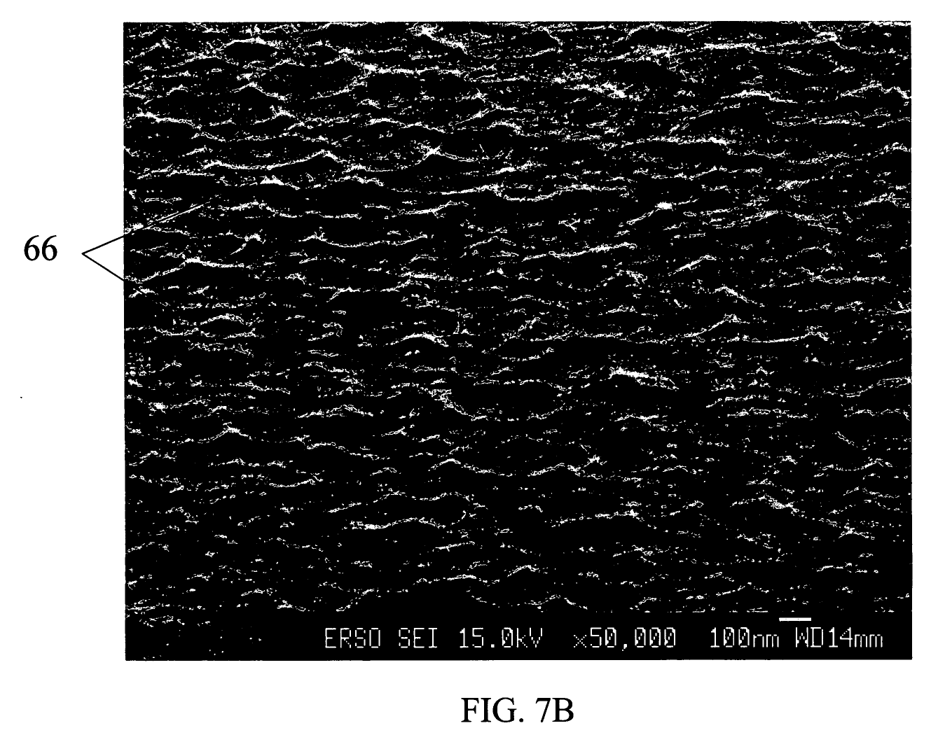

FIG. 7A is an SEM (Scanning Electron Microscope) photograph showing a polysilicon surface before an etching process. The surface roughness of the polysilicon film is approximately 120 Å. FIG. 7B is an SEM photograph showing a polysilicon surface after an etching process in accordance with one embodiment of the present invention with a time duration of 120 seconds. The surface roughness of the polysilicon film is reduced to approximately 80 Å. Referring to FIG. 7B, a plurality of slot-like recesses 66 are formed on the polysilicon surface after the second etching process.

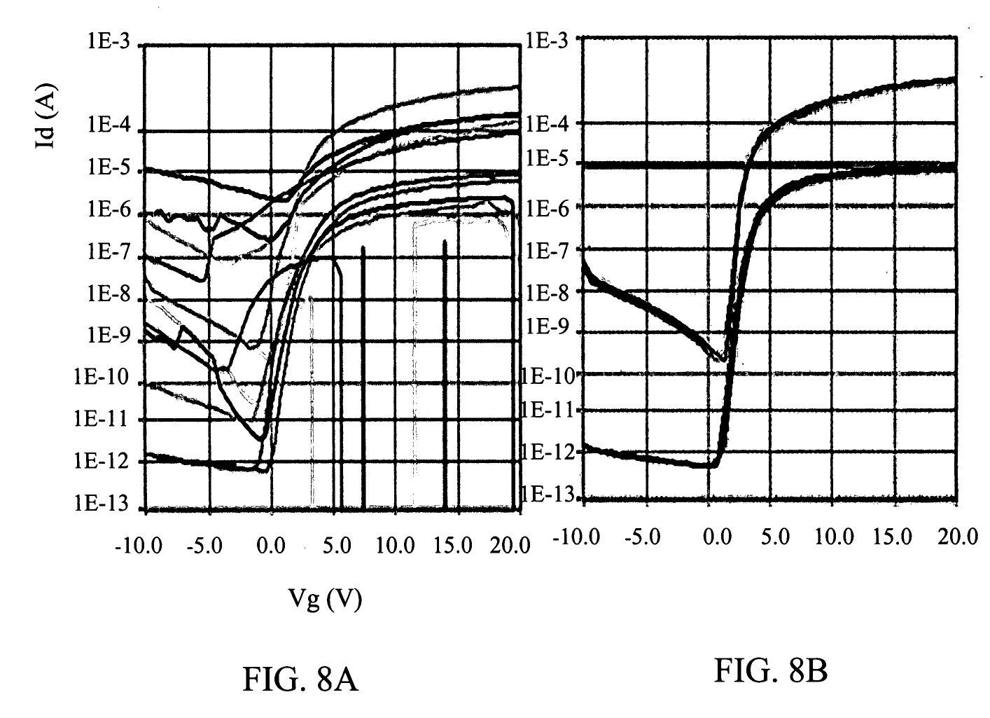

FIG. 8A is a drain current (Id) versus gate voltage (Vg) curve of a TFT having a polysilicon surface without planarization process. Referring to FIG. 8A, electrical properties cannot be measured in the TFT having a non-planarized surface. A rough polysilicon surface may cause a thin gate insulator of, for example, 500 Å to break down and a TFT thus fabricated to function abnormally. FIG. 8B is an Id-Vg curve of a TFT having a polysilicon surface planarized in accordance with a method of the present invention. Referring to FIG. 8B, general electrical properties are able to be measured in the planarized polysilicon TFT with a gate insulator of 500 Å.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

I claim:

1. A method for planarizing polysilicon, comprising:
providing a substrate;
forming a dielectric layer on the substrate;
forming an amorphous silicon film on the dielectric layer;
etching the amorphous silicon film to remove native oxide formed on a surface of the amorphous silicon film;
exposing the surface of the amorphous silicon film to a first radiation source to polycrystallize the amorphous silicon film into a polysilicon film;
etching the polysilicon film to remove weak bonded silicon formed on a surface of the polysilicon film; and
exposing the surface of the polysilicon film to a second radiation source to reflow the polysilicon film.

2. The method according to claim 1, further comprising etching the amorphous silicon film in an etchant comprising approximately a 40% solution of NH₄F and a 49% solution of HF to remove the native oxide.

3. The method according to claim 2, wherein the ratio of the HF solution to the NH₄F solution is approximately 1:20 to 1:30.

4. The method according to claim 1, further comprising etching the polysilicon film in an etchant comprising approximately a 40% solution of NH₄F and a 49% solution of HF to remove the weak bonded silicon.

5. The method according to claim 4, wherein the ratio of the HF solution to the NH₄F solution is approximately 1:2 to 1:4.

6. The method according to claim 1, further comprising etching the polysilicon film in an etchant comprising one of a solution of KOH, a solution of CrO₃ and HF, or a solution of HNO₃ and HF to remove weak bonded silicon.

7. The method according to claim 1, wherein the second radiation source has an energy density smaller than that of the first radiation source.

8. The method according to claim 1, wherein the second radiation source has an overlap ratio smaller than that of the first radiation source.

9. The method according to claim 1, further comprising forming recesses on the surface of the polysilicon film in etching the polysilicon film.

10. A method for planarizing polysilicon, comprising:
forming an amorphous silicon film over a substrate;
etching the amorphous silicon film in a first etchant comprising a first density of a hydrofluoric acid;
exposing the amorphous silicon film to a first radiation source to polycrystallize the amorphous silicon film into a polysilicon film;
etching the polysilicon film in a second etchant comprising a second density of a hydrofluoric acid greater than the first density; and
exposing the polysilicon film to a second radiation source to reflow the polysilicon film.

11. The method according to claim 10, wherein the first etchant includes approximately a 40% solution of NH₄F and a 49% solution of HF, and the first density of the HF solution to the NH₄F solution is approximately 1:20 to 1:30.

12. The method according to claim 10, wherein the second etchant includes approximately a 40% solution of NH₄F and a 49% solution of HF, and the second density of the HF solution to the NH₄F solution is approximately 1:2 to 1:4.

13. The method according to claim 10, further comprising forming recesses on the polysilicon film in etching the polysilicon film.

14. The method of claim 10, wherein the second radiation source has an energy density smaller than that of the first radiation source.

15. The method according to claim 10, wherein the second radiation source has an overlap ratio smaller than that of the first radiation source.

16. A method for planarizing polysilicon, comprising:
forming an amorphous silicon film over a substrate;
removing native oxide formed on a surface of the amorphous silicon film by a first etchant having a first density;
exposing the surface of the amorphous silicon film to a first radiation source to polycrystallize the amorphous silicon film into a polysilicon film, the polysilicon film having a plurality of ridges formed on a surface thereof;
recessing the ridges by using a second etchant having a second density greater than the first density; and
exposing the surface of the polysilicon film to a second radiation source to reflow the polysilicon film.

17. The method according to claim 16, wherein the first etchant includes approximately a 40% solution of NH₄F and a 49% solution of HF, and the first density of the HF solution to the NH₄F solution is approximately 1:20 to 1:30.

18. The method according to claim 16, wherein the second etchant includes approximately a 40% solution of NH₄F and a 49% solution of HF, and the second density of the HF solution to the NH₄F solution is approximately 1:2 to 1:4.

19. The method according to claim 16, wherein the first radiation source has an energy density greater than that of the second radiation source.

20. The method according to claim 16, wherein the first radiation source has an overlap ratio greater than that of the second radiation source.
